(19) United States
(12) Patent Application Publication
(10) Pub. No.: US 2009/0137125 A1
(43) Pub. Date: May 28, 2009

(54) ETCHING METHOD AND ETCHING APPARATUS

(75) Inventors: Toshihisa Nozawa, Tokyo (JP); Tetsuya Nishizuka, Tokyo (JP)

Correspondence Address: PEARNE & GORDON LLP, 1801 EAST 9TH STREET, SUITE 1200, CLEVELAND, OH, 44114-3108, US

(73) Assignee: TOKYO ELECTRON LIMITED, Tokyo (JP)

(21) Appl. No.: 12/091,961

(22) PCT Filed: Oct. 26, 2006
(86) PCT No.: PCT/JP2006/321410

§ 371 Date: Apr. 29, 2008

(30) Foreign Application Priority Data
Oct. 31, 2005 (JP) 2005-317367

(51) Int. Cl. H01L 21/3065

(52) U.S. Cl. 438/694; 156/345.26; 257/E21.218

(57) ABSTRACT

Disclosed is an etching method for etching a target layer formed on a surface of a target object, including: a resist forming step for forming a resist layer uniformly on the surface of the target object; a mask forming step for forming a patterned etching mask by forming an etching recess on the resist layer; a plasma resistant film forming step for forming a plasma resistant film on the entire surface of the etching mask including a bottom and a sidewall of the etching recess; a bottom plasma resistant film removing step for removing the plasma resistant film formed on the bottom of the etching recess; and a main etching step for etching the target layer by using the etching mask as a mask, after the bottom plasma resistant film removing step.

### TECHNICAL FIELD

The present invention relates to an etching method and an etching apparatus for etching a target layer such as an insulating film formed on a surface of a target object such as a semiconductor wafer.

### BACKGROUND ART

In general, to form an integrated circuit of a semiconductor product, various processes such as a film forming process, a reforming process, an oxidation/diffusion process, an etching process and so forth are repeatedly performed on a surface of a semiconductor wafer such as a silicon substrate or the like. As a result, a desired integrated circuit can be manufactured.

Among the mentioned various processes, the etching process will be explained for example. Generally, in the etching process, a patterned etching mask is formed on a surface of a target layer to be etched by using a photoresist or the like. By allowing an etching gas to act on the target layer while using the etching mask as a mask, only a desired portion of the target layer is selectively removed, so that the etching is performed only on the desired portion. Here, since the photoresist is generally formed of an organic material, its heat resistance is not high. Accordingly, in order to maintain the shape of the mask pattern and carry out the etching with a proper etching profile, the etching is required to be performed at a relatively low temperature of about 200° C. in consideration of the heat resistance of the mask. As an etching process under such a low temperature condition, a plasma etching using plasma has been generally performed (see, for example, Japanese Patent Laid-open Application No. H5-21396).

An example of a conventional etching method using plasma is described below with reference to FIGS. 4A to 4E. FIGS. 4A to 4E provide process sequence diagrams to describe an example of the conventional etching method using plasma.

As illustrated in FIG. 4A, a target layer 202 to be etched into a specific pattern is formed on a surface of a target object W which is made of a semiconductor wafer such as a silicon substrate or the like. The target layer 202 is an insulating film made of, for example, a SiO₂ film. In the figure, only a part of the top surface portion of the target object W is shown.

Further, an anti-reflection film 204 made of, for example, an organic material is uniformly formed on a top surface of the target layer 202 in advance to exclude an adverse influence of reflection light during a resist exposure process to be described later.

First, on the surface of the anti-reflection film 204 of the target object W thus formed, a resist layer 206 is uniformly formed in a preset thickness (see FIG. 4A). The resist layer 206 is then selectively exposed to light to be developed and a part thereof is selectively removed, so that an etching recess 208 is formed (see FIG. 4B). That is, an etching mask 210 made of the resist is obtained. The etching recess 208 may be of a groove shape or a hole shape depending on a pattern of the target layer 202 to be removed.

Subsequently, the anti-reflection film 204 exposed at the bottom of the etching recess 208 is removed by a plasma etching (see FIG. 4C), so that a surface of the target layer 202 is exposed. Then, a plasma etching is performed by using the etching mask 210 as a mask, whereby the target layer 202 formed of SiO₂ is etched (see FIG. 4D).

Thereafter, an ashing process using plasma is performed, so that the etching mask 210 and the anti-reflection film 204 made of the organic materials are eliminated, respectively (see FIG. 4E). Then, the whole etching process is completed.

When a line width, a groove width or a hole diameter is comparatively large, a desired etching process can be performed without suffering a deformation of the shape of the target layer 202. In pursuit of further high-integration and high-miniaturization, however, if a size of a line width or the like is required to be, for example, no greater than the order of about 150 nm, the resist layer 206 needs to be formed by using a special resist having a high transmittance even for short-wavelength light, to improve a resolution.

However, such special resist has a relatively poor plasma resistance. Accordingly, an opening 210A of the etching mask 210 made of the resist may be deformed and gradually expanded as a result of collision with the plasma during the plasma process, as illustrated in FIGS. 4C and 4D. As a consequence, an opening 212A of a groove 212 of the target layer 202 may be enlarged larger than expected, as described in FIGS. 4D and 4E. That is, the etching may not be performed with a proper etching profile, and a desired etching pattern may not be obtained.

In such a case, it may be attempted to enhance the thickness of the etching mask 210 by considering the amount of the etching mask 210 (resist layer 206) removed by the plasma. However, if the etching mask 210 (resist layer 206) is excessively thickened, there arises problems that, when the resist layer 206 is exposed and sensitized to light, the lower part of the resist layer 206 may not be sufficiently sensitized to light and that it may cause out of focus in a thickness direction of the resist layer 206. Thus, a maximum thickness of the etching mask 210 is no more than about 400 nm, and it is impossible to set the thickness of the etching mask 210 to be larger than that.

### DISCLOSURE OF THE INVENTION

In view of the foregoing, the present invention is conceived to effectively solve the problems. An object of the present invention is to provide an etching method and an etching apparatus capable of more securely obtaining a desired etching pattern without having a deformation by preventing a deformation of an etching mask by means of coating a plasma resistant film on the surface of the etching mask.

In accordance with the present invention, there is provided an etching method for etching a target layer formed on a surface of a target object, including: a resist forming step for forming a resist layer uniformly on the surface of the target object; a mask forming step for forming a patterned etching mask by forming an etching recess on the resist layer; a plasma resistant film forming step for forming a plasma resistant film on the entire surface of the etching mask including a bottom and a sidewall of the etching recess; a bottom plasma resistant film removing step for removing the plasma resistant film formed on the bottom of the etching recess; and a main etching step for etching the target layer by using the etching mask as a mask, after the bottom plasma resistant film removing step.

In accordance with the present invention, the plasma resistant film is formed on the entire surface of the etching mask, and the typical etching process for removing the target layer is carried out after the plasma resistant film located on the bottom of the etching recess of the etching mask is eliminated. Therefore, a deformation of the etching mask can be effectively prevented, so that a desired etching pattern without having a deformation can be obtained more securely.

For example, a thickness of the plasma resistant film formed on the bottom of the etching recess is smaller than a thickness of the plasma resistant film formed on a top surface of the etching mask.

Further, for example, the plasma resistant film is formed by a plasma CVD process at a temperature lower than a heat resistant temperature of the etching mask.

Furthermore, desirably, an anti-reflection film is formed on a surface of the target layer in advance. In this case, for example, prior to or after the plasma resistant film forming step, a bottom anti-reflection film removing step for removing the anti-reflection film located on the bottom of the etching recess is performed.

Moreover, for example, after the main etching step, a plasma resistant film removing step for removing the plasma resistant film and a mask removing step for removing the mask are performed in sequence.

For example, a part or all of the plasma resistant film forming step, the bottom plasma resistant film removing step and the main etching step are performed in the same plasma processing apparatus.

In accordance with the present invention, there is provided an etching apparatus for performing an etching process on a target object, including: a processing chamber evacuable to vacuum; a mounting table, disposed in the processing chamber, for mounting the target object thereon; a gas introduction unit for introducing a gas into the processing chamber; a plasma generation unit for converting the gas into a plasma in the processing chamber; and a control unit for controlling the gas introduction unit and the plasma generation unit to perform a part or all of a plasma resistant film forming step for forming a plasma resistant film on the entire surface of an etching mask formed on a surface of a target layer of the target object, a bottom plasma resistant film removing step for removing the plasma resistant film formed on a bottom of an etching recess formed on the etching mask, and a main etching step for etching the target layer by using, as a mask, the etching mask which is covered with the plasma resistant film except the bottom of the etching recess.

In accordance with the present invention, there is provided a storage medium storing therein a computer program which allows a computer to execute a control method for controlling an etching apparatus including: a processing chamber evacuable to vacuum; a mounting table, disposed in the processing chamber, for mounting a target object

[symbol]

### BRIEF DESCRIPTION OF THE DRAWINGS

FIG. 1 provides a schematic cross sectional view of an etching apparatus in accordance with an embodiment of the present invention.

FIGS. 2A to 2H present process sequence diagrams to describe an etching method in accordance with a first embodiment of the present invention.

FIGS. 3A to 3H set forth process sequence diagrams to describe an etching method in accordance with a second embodiment of the present invention.

FIGS. 4A to 4E depict process sequence diagrams to describe a conventional etching method using plasma.

### BEST MODE FOR CARRYING OUT THE INVENTION

Hereinafter, an etching apparatus and an etching method in accordance with an embodiment of the present invention will be described in detail with reference to the accompanying drawings.

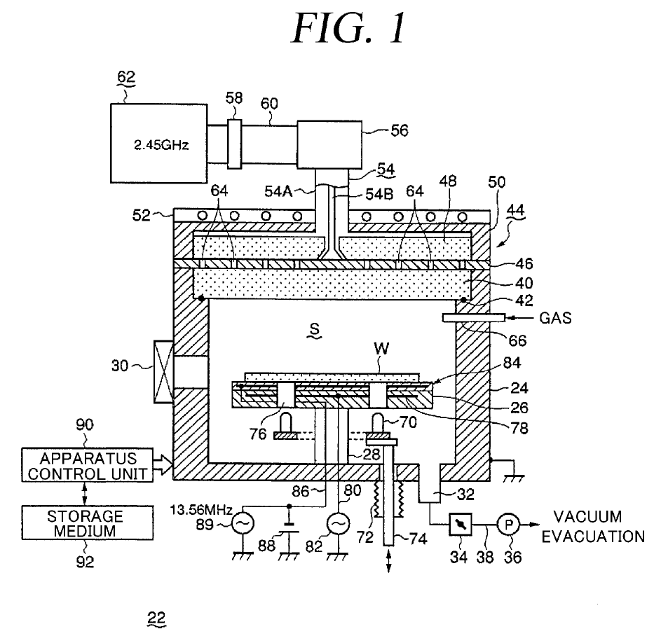

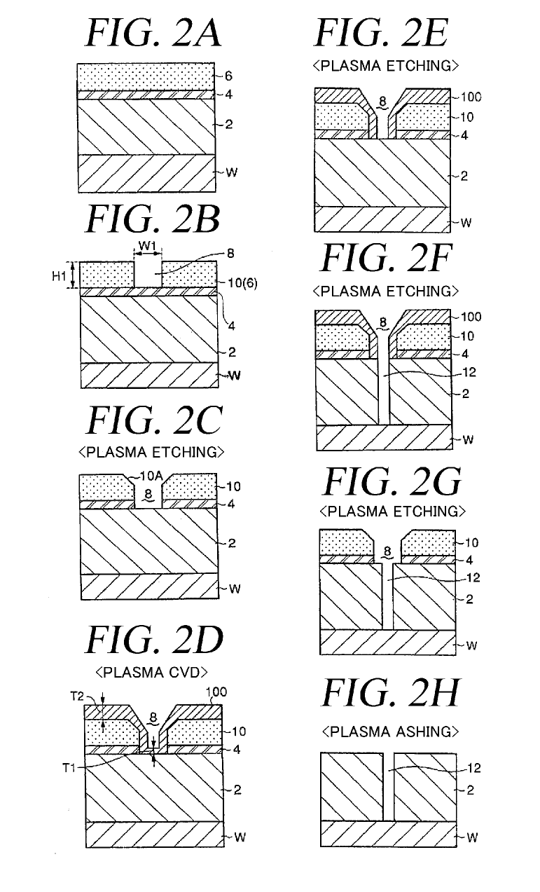

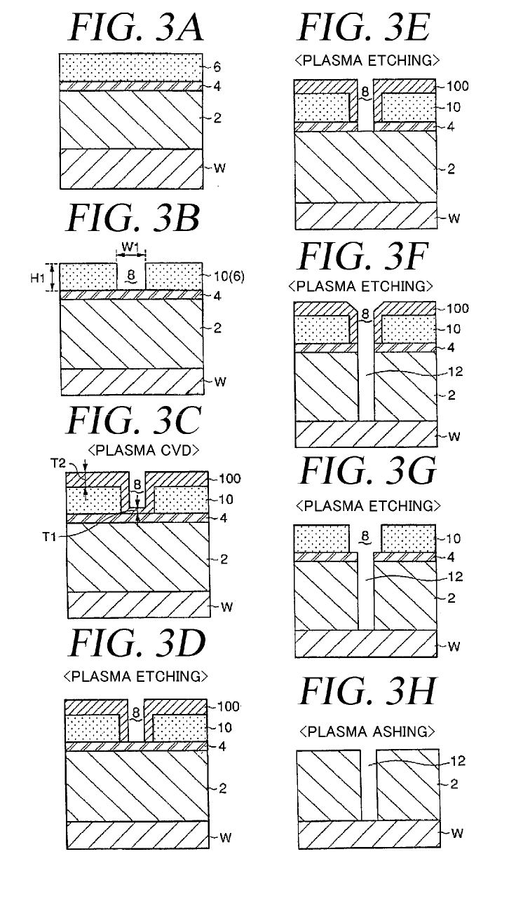

FIG. 1 is a schematic cross sectional view showing an etching apparatus in accordance with an embodiment of the present invention. FIGS. 2A to 2H provide process sequence diagrams to describe an etching method in accordance with a first embodiment of the present invention, and FIGS. 3A to 3H present process sequence diagrams to explain an etching method in accordance with a second embodiment of the present invention. Here, a plasma etching process is performed by using plasma generated by a microwave.

As shown in FIG. 1, the etching apparatus (plasma etching apparatus) 22 in accordance with the embodiment of the present invention includes a processing chamber 24 formed in a cylindrical shape as a whole. A sidewall and a bottom portion of the processing chamber 24 are made of a conductor such as aluminum or the like, and are grounded. The inside of the processing chamber 24 is configured as an airtightly sealed processing space S, and plasma is generated in this processing space S.

Disposed inside the processing chamber 24 is a mounting table 26 for mounting a target object to be processed, e.g., semiconductor wafer W, on a top surface thereof. The mounting table 26 is of a flat circular-plate shape made of, for example, alumite-treated aluminum, ceramic, or the like. The mounting table 26 is sustained on a supporting column 28 which is made of, for example, aluminum or the like and protrudes from the bottom portion of the processing chamber 24.

Installed at the sidewall of the processing chamber 24 is a gate valve 30 which is opened/closed, whereby the wafer is loaded into or unloaded from the inside of the processing chamber 24. Further, a gas exhaust port 32 is provided at the bottom portion of the processing chamber 24. Connected to the gas exhaust port 32 is a gas exhaust path 38 on which a pressure control valve 34 and a vacuum pump 36 are installed in sequence. With this arrangement, the inside of the processing chamber 24 can be evacuated to a specific pressure level as required.

Moreover, a ceiling portion of the processing chamber 24 is opened (or has an opening). A microwave transmissive ceiling plate 40 is airtightly provided at the opening via a sealing member 42 such as an O ring. The ceiling plate 40 is made of, for example, a ceramic material such as Al₂O₃. The thickness of the ceiling plate 40 is set to be, for example, about 20 mm in consideration of pressure resistance.

Disposed on a top surface of the ceiling plate 40 is a plasma generating unit 44 for generating plasma in the processing chamber 24 by a microwave. Specifically, the plasma generating unit 44 has a circular plate shaped planar antenna member 46 disposed on a top surface of the ceiling plate 40 and a wave-delay member 48 is disposed on the planar antenna member 46. The wave-delay member 48 has a high-permittivity property to shorten the wavelength of the microwave. A substantially entire surface of the top portion and the sidewall portion of the wave-delay member 48 is enclosed by a waveguide box 50 made of a conductive chamber of a hollow cylindrical shape. The planar antenna member 46 is configured as a bottom plate of the waveguide box 50, and is provided to face the mounting table 26. On top of the waveguide box 50, there is disposed a cooling jacket 52 for flowing a coolant to cool the waveguide box 50.

The peripheral portions of the waveguide box 50 and the planar antenna member 46 are electrically connected with the processing chamber 24. Further, an external tube 54A of a coaxial waveguide 54 is connected to a center of the top portion of the waveguide box 50, and an internal conductor 54B of the coaxial waveguide 54 is connected to the central portion of the planar antenna member 46 via a through hole provided in the center of the wave-delay member 48.

The coaxial waveguide 54 is connected to a microwave generator 62 for generating a microwave of, e.g., about 2.45 GHz via a waveguide 60 on which a mode converter 56 and a matching circuit 58 are installed. The coaxial waveguide 54 with this arrangement serves to transmit the microwave to the planar antenna member 46. The frequency of the microwave is not limited to 2.45 GHz, but another frequency, e.g., about 8.35 GHz, can be used.

When designed to correspond to a wafer having a size of about 300 mm, the planar antenna member 46 is made of a conductive material having a diameter of, e.g., about 400 to 500 mm and a thickness of, e.g., about 1 to several mm. To elaborate, the planar antenna member 46 can be made of an aluminum or copper plate whose surface is plated with silver. Further, the planar antenna member 46 is provided with a number of slots 64 having, for example, a shape of an elongated through hole. The arrangement of the slots 64 is not limited to a specific pattern. For instance, they can be arranged in concentric, spiral or radial pattern or can be uniformly distributed over the entire surface region of the planar antenna member.

A gas introduction unit 66 for introducing a gas needed in an etching process into the processing chamber 24 is disposed above the mounting table 26. Specifically, the gas introduction unit 66 is, for example, a gas nozzle made of, e.g., quartz glass. A desired gas is supplied from the gas nozzle 66 when necessary, while its flow rate is being controlled. The gas introduction unit 66 may include a plurality of gas nozzles depending on types of gases employed. Furthermore, the gas introduction unit 66 may be configured as a shower head made of quartz glass.

Further, installed below the mounting table 26 are a plurality of, e.g., three elevating pins 70 (only two are shown in FIG. 1) for lifting or lowering the wafer W when the wafer W is loaded or unloaded. The elevating pins 70 are moved up and down by an elevation rod 74 which is provided to go through the bottom portion of the processing chamber 24 via an extendible and contractible bellows 72. Moreover, pin insertion holes 76 for allowing the elevating pins 70 to move therethrough are provided in the mounting table 26.

The mounting table 26 is made of a heat resistant material, e.g., ceramic such as alumina, and a heating unit 78 is disposed in this heat resistant material, as necessary. The heating unit 78 of the present embodiment has a thin-plate shaped resistance heater buried in the mounting table 26 substantially over the entire region thereof. The resistance heater 78 is connected to a heater power supply 82 via a wiring 80 which is provided through the supporting column 28. Further, a cooling unit (not shown) such as a cooling jacket is installed in the mounting table 26, if necessary, whereby the semiconductor wafer W can be cooled to a specific temperature level.

Disposed on the top surface of the mounting table 26 is a thin electrostatic chuck 84 having therein a conductor line arranged in, e.g., a mesh pattern. The conductor line of the electrostatic chuck 84 is connected to a DC power supply 88 via a wiring 86 to exert an electrostatic adsorptive force. With this arrangement, the semiconductor wafer W placed on the mounting table 26, specifically, on the electrostatic chuck 84 can be attracted to and firmly held on the electrostatic chuck 84 by the electrostatic adsorptive force. Further, connected to the wiring 86, if necessary, is a bias high frequency power supply 89 for applying a bias high frequency power of, e.g., 13.56 MHz to the conductor line of the electrostatic chuck 84.

The whole operation of the etching apparatus 22 is controlled by an apparatus control unit 90 made up of, e.g., a microcomputer or the like. Computer executable programs for executing the operation of the etching apparatus 22 are stored in a storage medium 92 such as a flexible disk, a CD (Compact Disk), a flash memory, a hard disk, and the like. Specifically, a supply and a flow rate of each gas, a supply and a power of a microwave or a high frequency wave, a process temperature, a process pressure, and the like are controlled by commands from the apparatus control unit 90.

Below, an etching method, which is performed by using the etching apparatus 22 having the above-described configuration, will be explained with reference to FIG. 1 and FIGS. 2A to 2H.

### First Embodiment

First, a first embodiment of an

[symbol]

As shown in FIG. 2A, a target layer 2 to be etched into a specific pattern is formed on a surface of a target object W which is made of a semiconductor wafer such as a silicon substrate. The target layer 2 is an insulating film formed of, for example, a SiO₂ film. In the figure, only a part of the top surface portion of the target object is shown.

Further, an anti-reflection film 4 made of, for example, an organic material is uniformly formed on a top surface of the target layer 2 in advance to exclude an adverse influence of reflection light during a resist exposure process to be described later. BARC (Bottom Anti-Reflection Coating: brand name) may be used as the anti-reflection film 4, for example.

Meanwhile, a photoresist film is coated on the surface of the anti-reflection film 4 of the target object W thus formed, so that a resist layer 6 is uniformly formed in a specific thickness (see FIG. 2A). Then, this resist forming process is completed.

Then, the resist layer 6 is selectively exposed to light to be developed and a part of the resist layer 6 is selectively removed, so that an etching recess 8 is formed (see FIG. 2B). That is, an etching mask 10 made of the resist is formed (see FIG. 2B). The etching recess 8 may be of a groove shape or a hole shape depending on a pattern of the target layer 2 to be removed. Further, the underlying anti-reflection film 4 is exposed at the bottom portion of the etching recess 8. Here, the width W1 of the etching recess 8 is about 150 nm or less, and the height H1 of the etching mask 10 is in the range of, for example, about 300 to 400 nm. Through this process, the mask forming step is completed.

Subsequently, a plasma etching process and a plasma CVD process are performed by using the etching apparatus (plasma processing apparatus) 22 shown in FIG. 1. To carry out these plasma processes, the semiconductor wafer W as shown in FIG. 2B is first loaded into the processing chamber 24 by a transfer arm (not shown) through the gate valve 30. By moving the elevating pins 70 up and down, the semiconductor wafer W is placed on a mounting surface, i.e., the top surface of the mounting table 26. Then, the semiconductor wafer W is attracted and held by the electrostatic chuck 84 electrostatically.

The semiconductor wafer W is maintained at a certain process temperature by the heating unit 78 or the cooling unit. Meanwhile, a processing gas is supplied into the processing chamber 24 via the gas introduction unit 66 at a specific flow rate. The inner pressure of the processing chamber 24 is kept at a certain process pressure level by controlling the pressure control valve 34. At the same time,

[symbol]

To elaborate, if the microwave is introduced into the processing chamber 24 from the planar antenna member 46, the gas supplied to the processing space S is converted into plasma and activated by the microwave. By active species generated at that time, the surface of the semiconductor wafer W can be efficiently plasma-processed (for example, an etching process or a film forming process is carried out) even under a low temperature condition. At this time, by operating, for example, the bias high frequency power supply 89, ions in the plasma can be more strongly attracted toward the mounting table 26.

Here, after the semiconductor wafer W as shown in FIG. 2B is loaded into the plasma processing apparatus 22 as described above, the anti-reflection film 4 exposed at the bottom of the etching recess 8 is removed by the plasma etching as shown in FIG. 2C. As a result, a surface of the target layer 2 is exposed. An etching gas used for this step may be an Ar gas, a CF-based gas such as a C₅F₈ gas, an O₂ gas, and the like. Further, a process temperature in this step is set to be, for example, about 130° C. or less in consideration of heat resistance of the etching mask 10. Though an opening 10A of the etching recess 8 of the etching mask 10 is slightly removed by the plasma etching process, it does not incur any particular problem. Through the process described, this bottom anti-reflection coating film removing step is completed.

Subsequently, on the entire surface of the etching mask 10 including the bottom and the sidewall of the etching recess 8, a plasma resistant film 100 is formed by a plasma CVD process, as illustrated in FIG. 2D. The plasma resistance film 100 has a high resistance to the plasma, and is an inventive feature of the present invention. As a result, the entire surface of the etching mask 10 is covered with the plasma resistant film 100. As the plasma resistance film 100, a silicon nitride film (SiN) can be used, for example. Here, it should be noted that it is difficult for a film forming gas to infiltrate the inside of the etching recess 8 due to a very narrow width W1 of the etching recess 8. Therefore, a thickness T1 of the plasma resistant film 100 deposited on the bottom and the sidewall of the etching recess 8 becomes much smaller than a thickness T2 of the plasma resistance film 100 deposited on the top surface of the etching mask 10. For example, though varied depending on the width W1 or the height H1 of the etching recess 8, the thickness ratio T1/T2 is about 0.5. In this embodiment, the plasma resistance film 100 is formed such that the thicknesses T1 and T2 are, for example, 5 nm and 10 nm, respectively.

In this step, a process temperature is set to be, for example, about 130° C. or less in consideration of the heat resistance of the etching mask 10. Furthermore, a silane-based gas and a nitriding gas are used as the film forming gas at this time. Here, the silane-based gas may be a SiH₄ gas or a Si₂H₆ gas, and the nitriding gas may be an N₂ gas, a NH₃ gas, or the like. Moreover, it is also possible to add a nonreactive gas such as an Ar gas to these gases. Through the aforementioned process, the plasma resistant film forming step is completed.

Subsequently, as shown in FIG. 2E, a plasma etching process for removing the plasma resistant film 100 deposited on the bottom of the etching recess 8 is carried out. In this case, though the plasma resistant film 100 deposited on the top surface of the etching mask 10 is also removed, only the plasma resistant film 100 on the bottom of the etching mask 10 can be completely eliminated, because the film thickness T2 on the top surface of the etching mask 10 is much larger than the film thickness T1 on the bottom of the etching recess 8, as mentioned above. As a result, the surface of the underlying target layer 2 is exposed at the bottom of the etching recess 8. At this time, if a bias power of about 13.56 MHz for ion attraction is applied to the mounting table 26 by operating the bias high frequency power supply 89, the plasma resistant film 100 deposited on the bottom of the etching recess 8 can be more efficiently eliminated.

In this step, a CF-based gas such as a CF₄ gas, a CHF₃ gas or the like can be employed as an etching gas. Further, a process temperature is set to be about 130° C. or less in consideration of the heat resistance of the etching mask 10. Through the aforementioned process, this bottom plasma resistant film removing step is completed.

Thereafter, as shown in FIG. 2F, a plasma etching process of the target layer 2 is performed by using the etching mask 10, which is covered with the plasma resistant film except for the bottom of the etching recess 8, as a mask. As a result, the target layer 2 made of, for example, a SiO₂ is etched while the pattern of the etching mask 10 covered with the plasma resistant film is transcribed thereto, so that a processed groove 12 is formed. At the bottom of the groove 12, the surface of the underlying semiconductor wafer W is exposed.

In this step, a process temperature is set to be about 130° C. or less in consideration of the heat resistance of the etching mask 10, and an etching gas may include, for example, an Ar gas, a CF-based gas made up of a CF₄ gas, and the like.

In such case, since the plasma resistant film 100 made of SiN is also removed by this plasma etching process, the entire thickness of the plasma resistant film 100 is reduced. However, since the selectivity of the etching gas for the SiO₂ of the target layer 2 against the SiN of the plasma resistant film 100 is about 10 to 50, the plasma resistant film 100 would not be completely removed while the target layer 2 formed of the SiO₂ is eliminated relatively easily. That is, the shape of the etching mask 10 is maintained without being deformed. If an etching gas containing a C₅F₈ gas is used, the selectivity can be further improved.

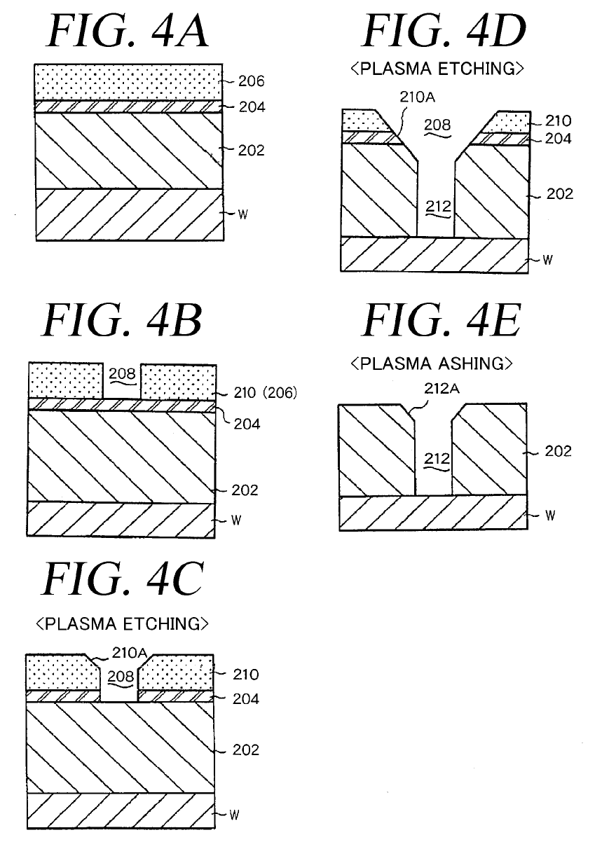

Accordingly, though, in the prior art method, an etching pattern is deformed as illustrated in FIGS. 4D and 4E, a deformation of the etching mask 10 is prevented in accordance with the present invention as described above, so that a desired etching pattern without having a pattern deformation can be securely obtained. Through the above-described process, the etching step is finished.

Subsequently, as shown in FIG. 2G, a plasma etching process for completely removing the plasma resistant film 100 made of SiN covering the surface of the etching mask 10 is performed. In this step, on the contrary to the case of FIG. 2F, an etching gas capable of easily removing the plasma resistant film 100 of SiN while hardly etching the target layer 2 of SiO₂ is employed. To be specific, a selectivity, which is reverse to that of the case described in FIG. 2F, can be obtained by controlling a CF₄ gas of a CF-based gas as the etching gas with an appropriate concentration or by using a CHF₃ gas, for example. As a result, it is possible to selectively remove the plasma resistant film 100 covering the surface of the etching mask 10 while maintaining the shape of the target layer 2 made of SiO₂. Through the above-described process, the plasma resistant film removing step is completed.

Then, as illustrated in FIG. 2H, a plasma ashing process is performed by using, for example, oxygen plasma. To elaborate, a mask removing step for removing the etching mask 10 made of an organic material is carried out, and, subsequently, an anti-reflection film removing step for removing the anti-reflection film 4 which is also made of an organic material is performed. Consequently, the etching mask 10 and the anti-reflection film 4 are completely eliminated. Thus, through the above-described process, the whole etching process is finally completed.

In the method in accordance with the embodiment of the present invention, after the plasma resistant film 100 is formed on the entire surface of the etching mask 10 and the plasma resistant film 100 deposited on the bottom of the etching recess 8 of the etching mask 10 is removed, the typical etching process for removing the target layer 2 is performed. Therefore, a deformation of the etching mask can be prevented, and a desired etching pattern without having a shape deformation can be obtained more securely.

In the above-described embodiment, though the types of gases used for the processes from the plasma etching process shown in FIG. 2C to the plasma ashing process shown in FIG. 2H are changed and supplied, such serial processes are continually conducted in the same plasma processing apparatus 22 illustrated in FIG. 1. However, without being limited to this embodiment, only some of the processes shown in FIGS. 2C to 2H may be performed in the plasma processing apparatus 22 of FIG. 1, while others may be carried out in separate processing apparatuses. For example, it is possible to perform the plasma etching process, the plasma CVD process, and the plasma ashing process in individual processing apparatuses for their own purposes. Furthermore, it is also possible to perform the respective processing steps shown in FIGS. 2C to 2H in their own individual processing apparatuses.

### Second Embodiment

Now, a second embodiment of a method of the present invention will be explained.

FIGS. 3A to 3H set forth process sequence diagrams to describe the etching method in accordance with the second embodiment of the present invention. In the aforementioned first embodiment, through each step shown in FIGS. 2C to 2E, after the etching mask 10 is formed, the anti-reflection film 4 exposed on the bottom of the etching recess 8 is removed (see FIG. 2C). Subsequently, the plasma resistant film 100 is deposited on the entire surface of the etching mask 10 (see FIG. 2D), and, then, the plasma resistant film 100 disposed on the bottom of the etching recess 8 is eliminated (see FIG. 2E). However, without being limited to this sequence, it is also possible to deposit the plasma resistant film 100 first and then to remove the plasma resistant film 100 and the anti-reflection film 4 located on the bottom of the etching recess 8 in sequence. That is, in this embodiment, processing steps illustrated in FIGS. 3A and 3B correspond to the processing steps of FIGS. 2A and 2B, respectively, and after the formation of an etching mask 10 is completed as illustrated in FIG. 3B, a plasma resistant film 100 is formed on the entire surface of the etching mask 10, as shown in FIG. 3C.

Then, as illustrated in FIG. 3D, the plasma resistant film 100 located on the bottom of an etching recess 8 is removed, and, as shown in FIG. 3E, the anti-reflection film 4 exposed at the bottom of the etching recess 8 is eliminated.

Subsequent each processing step shown in FIGS. 3F to 3H corresponds to each processing step shown in FIGS. 2F to 2H, respectively.

In the second embodiment described above, the same function and effect as obtained in the first embodiment can be achieved.

Further, though the aforementioned embodiments have been described for the case of using the silicon nitride film (SiN) as the plasma resistant film 100, the present invention is not limited thereto. For example, a SiCN film, a SiC film, a SiCO film, a Si film, or the like can be employed instead of the SiN film. Besides, these exemplary films, including the SiN film, may contain hydrogen therein, though the amount of the hydrogen is insignificant. Even such case is considered to be included in the scope of the present invention. Further, when a film containing Si and C is formed as the plasma resistant film 100 at a low temperature (less than or equal to 130° C.), it is desirable to utilize, at least, trimethylsilane.

In the event that the above-specified films are used as the plasma resistant film 100, a CF₄ gas or a CHF₃ gas may be used to remove these films through a plasma etching process, as in the case of using the SiN film.

Further, in the above-described embodiments, an example, in which the insulating film made of SiO₂, as the target layer 2, is plasma-etched, has been described. However, the present invention is not limited thereto. That is, the method of the present invention can be applied to the etching of other types of insulating films as well.

Besides, the target layer 2 is not limited to the insulating film, either. For example, the method of the present invention can also be applied to the etching of a conductive polysilicon film. In such case, among the above-exemplified various films available as the plasma resistant film 100 when the target layer 2 is the SiO₂ film, all except the Si film can be used as the plasma resistant film 100.

Further, the plasma processing apparatus shown in FIG. 1 is nothing more than an example. The present invention can be applied to all types of plasma processing apparatus using a microwave or a high frequency wave.

Besides, the target object to be processed is not limited to the semiconductor wafer, but can be a LCD substrate, a glass substrate, a ceramic substrate, or the like.

1. An etching method for etching a target layer formed on a surface of a target object, comprising:
a resist forming step for forming a resist layer uniformly on the surface of the target object;
a mask forming step for forming a patterned etching mask by forming an etching recess on the resist layer;
a plasma resistant film forming step for forming a plasma resistant film on the entire surface of the etching mask including a bottom and a sidewall of the etching recess by a plasma CVD process at a process temperature less than or equal to about 130° C.;
a bottom plasma resistant film removing step for removing the plasma resistant film formed on the bottom of the etching recess; and
a main etching step for etching the target layer by using the etching mask as a mask, after the bottom plasma resistant film removing step.

2. The etching method of claim 1, wherein a thickness of the plasma resistant film formed on the bottom of the etching recess is smaller than a thickness of the plasma resistant film formed on a top surface of the etching mask.

3. The etching method of claim 1, wherein the plasma resistant film is formed by a plasma CVD process at a temperature lower than a heat resistant temperature of the etching mask.

4. The etching method of claim 1, wherein an anti-reflection film is formed on a surface of the target layer in advance.

5. The etching method of claim 4, wherein, prior to or after the plasma resistant film forming step, a bottom anti-reflection film removing step for removing the anti-reflection film located on the bottom of the etching recess is performed.

6. The etching method of claim 1, wherein, after the main etching step, a plasma resistant film removing step for removing the plasma resistant film and a mask removing step for removing the mask are performed in sequence.

7. The etching method of claim 1, wherein a part or all of the plasma resistant film forming step, the bottom plasma resistant film removing step and the main etching step are performed in the same plasma processing apparatus.

8. An etching apparatus for performing an etching process on a target object, comprising:
a processing chamber evacuable to vacuum;
a mounting table, disposed in the processing chamber, for mounting the target object thereon;
a gas introduction unit for introducing a gas into the processing chamber;
a plasma generation unit for converting the gas into a plasma in the processing chamber; and
a control unit for controlling the gas introduction unit and the plasma generation unit to perform a part or all of a plasma resistant film forming step for forming a plasma resistant film on the entire surface of an etching mask formed on a surface of a target layer of the target object by a plasma CVD process at a process temperature less than or equal to about 130° C., a bottom plasma resistant film removing step for removing the plasma resistant film formed on a bottom of an etching recess formed on the etching mask, and a main etching step for etching the target layer by using, as a mask, the etching mask which is covered with the plasma resistant film except the bottom of the etching recess.

9. A storage medium storing therein a computer program which allows a computer to execute a control method for controlling an etching apparatus comprising:
a processing chamber evacuable to vacuum;
a mounting table, disposed in the processing chamber, for mounting a target object thereon;
a gas introduction unit for introducing a gas into the processing chamber; and
a plasma generation unit for converting the gas into a plasma in the processing chamber,
wherein the control method controls the gas introduction unit and the plasma generation unit to perform a part or all of a plasma resistant film forming step for forming a plasma resistant film on the entire surface of an etching mask formed on a surface of a target layer of the target object by a plasma CVD process at a process temperature less than or equal to about 130° C., a bottom plasma resistant film removing step for removing the plasma resistant film formed on a bottom of an etching recess formed on the etching mask, and a main etching step for etching the target layer by using, as a mask, the etching mask which is covered with the plasma resistant film except the bottom of the etching recess.
